(19) United States
(12) Patent Application Publication
(10) Pub. No.: US 2011/0224085 A1
(43) Pub. Date: Sep. 15, 2011

(54) MAGNESIUM DIBORIDE

(75) Inventor: Friedrich Wilhelm Karau, Goslar (DE)

(73) Assignee: H.C. STARCK GMBH, Goslar (DE)

(21) Appl. No.: 13/128,408

(22) PCT Filed: Oct. 19, 2009
(86) PCT No.: PCT/EP2009/063641

§ 371 Date: May 31, 2011

Related U.S. Application Data
(60) Provisional application No. 61/113,369, filed on Nov. 11, 2008.

(30) Foreign Application Priority Data
Nov. 11, 2008 (DE) 10 2008 056 824.4

(51) Int. Cl. H01L 39/24; C01B 35/04; B32B 5/16

(52) U.S. Cl. 505/433; 423/289; 428/402; 29/599

(57) ABSTRACT

An amorphous or a partially crystalline magnesium diboride comprising a crystalline material content of ≦25% by weight as determined by an X-ray powder diffraction.

### CROSS REFERENCE TO PRIOR APPLICATIONS

This application is a U.S. National Phase application under 35 U.S.C. §371 of International Application No. PCT/EP2009/063641, filed on Oct. 19, 2009 and which claims benefit to German Patent Application No. 10 2008 056 824.4, filed on Nov. 11, 2008 and to U.S. Patent Application No. 61/113,369, filed on Nov. 11, 2008. The International Application was published in German on May 20, 2010 as WO 2010/054914 A1 under PCT Article 21(2).

### FIELD

The present invention provides an amorphous or a partially crystalline magnesium diboride comprising a crystalline material content of <25%, a process for producing the magnesium diboride, its use, as well as a process for producing superconducting wires containing the magnesium diboride.

### BACKGROUND

Magnesium diboride is a metallic chemical compound which at present has the highest transition temperature among metallic superconductors, namely 39 K. The cooling necessary for superconduction can also be generated by means of refrigeration machines; cooling by means of liquid helium can be dispensed with at this relatively high transition temperature.

Various processes for preparing magnesium diboride are known from the prior art.

Hanada et al. J. Mater. Chem. 18 (2008), 2611-2614 describe a process for preparing magnesium diboride by the thermal decomposition of magnesium borohydride (Mg(BH₄)₂) under a helium atmosphere or various hydrogen pressures. This study has the objective of examining magnesium borohydride (Mg(BH₄)₂) as a material for the reversible storage of hydrogen for the purposes of hydrogen storage technology. It was established that magnesium borohydride (Mg(BH₄)₂) decomposes mainly in the range of from 250 to 410° C. and that with increasing temperature, magnesium hydride (MgH₂) is formed. After a further temperature increase of from 410 to 580° C., the magnesium hydride (MgH₂) likewise gives off hydrogen, and crystalline magnesium diboride (MgB₂) can be detected by X-ray diffraction analysis.

Chlopek et al. J. Mater. Chem. 17 (2007), 3496-3503, describe a process for preparing magnesium borohydride (Mg(BH₄)₂) and its thermodynamic properties with the intention of using this compound as a medium for the reversible storage of hydrogen gas. As processes for the preparation of magnesium borohydride (Mg(BH₄)₂), mention is made of the metathesis reaction of magnesium chloride with lithium borohydride or sodium borohydride. A direct synthesis of Mg(BH₄)₂ from magnesium hydride and triethyl-amine-borane adduct is also mentioned. In the decomposition reaction of Mg(BH₄)₂ at temperatures of 450° C. and above, MgB₂ together with Mg and further unknown products were detected by X-ray diffraction analysis.

US 2007/0286 787 A1 describes a process for preparing crystalline magnesium borohydride from magnesium alkyls or magnesium alkoxides and a base-stabilized borane in a hydrocarbon solvent.

EP 1 842 838 A2 describes a process for preparing superconducting materials in which powders containing magnesium, boron and magnesium diboride and having a core-shell structure are processed by means of the “powder-in-tube technology” to produce superconducting wires. The reaction to form magnesium diboride is carried out under an argon atmosphere in the range of from 400 to 900° C.

WO 2006/040199 describes a process for preparing magnesium diboride in which powders composed of elemental magnesium and boron are mixed with one another and pressed and a current pulse is subsequently passed through the compact so as to lead to a plasma discharge in the voids between the particles to make the preparation of dense MgB₂ materials possible.

DE 10 2004 014 315 A1 describes a process for preparing boron-rich single-crystal metal borides by means of a reaction melt having a particular boron:metal ratio.

Magnesium diboride is also prepared in the prior art by the following process. A mixture of elemental magnesium and elemental boron is prepared and subsequently subjected to a furnace process at temperatures of from 800° C. to 1200° C. under argon as a protective gas. This reaction is strongly exothermic. The process has the disadvantage that it does not provide pure magnesium diboride, i.e., oxygen-free magnesium diboride, but owing to the high affinity of the metals magnesium and boron for oxygen always provides magnesium diboride containing oxidic impurities which reduce its suitability as a superconducting material. When this process is carried out industrially, contamination of the magnesium diboride with oxidic impurities is therefore virtually impossible to avoid. The oxidic impurities cannot be removed by reduction with hydrogen since boron hydrides would be formed from the elemental boron.

A further disadvantage of this process is that the magnesium diboride obtained has a coarse (>250 μm) and multimodal particle size distribution—a situation which makes further use as powder filling material for MgB₂ superconductor wires difficult. Owing to the highly exothermic nature of the reaction and the resulting heating of the mixture, the magnesium diboride powder obtained is not sufficiently sinter active. The reaction proceeds with melting of the magnesium.

WO 02/072 501 describes a further process for preparing magnesium diboride which comprises preparing a mixture of crystalline magnesium and amorphous boron as in the above-described process followed by mechanical alloying of the starting materials under argon. This enables the reaction temperature to be reduced considerably.

The advantage of the magnesium diboride prepared by the latter process is that it is more suitable as a powder filling material for MgB₂ superconductor wires than the MgB₂ prepared by synthesis from the elements according to the above processes.

The disadvantage of this process is that the mechanical alloying is very time-consuming and also increases contamination of the material, for example, by abraided material. After the furnace process, the powder must nevertheless be milled since, although it is obtained in finer form than in the first, conventional process, it still contains a considerable proportion of oversize particles. This second product milling increases the proportion of impurities in the powder further, takes time and limits the throughput. To keep the oxidic contamination as low as possible, magnesium hydride is added during milling of the product. Doping constituents can also be added to the powder before milling.

A problem in the production of superconducting magnesium diboride wires is the oxygen content of the magnesium diboride. Magnesium diboride is sensitive to oxygen and moisture. The disadvantageous materials property of magnesium diboride, which is, however, inherent in the chemical nature of this compound, is not disadvantageous in the finished filled wire itself since the filling material of the wire is sealed from air. Even if the greatest care is taken in the preparation of magnesium diboride from the elements magnesium and boron and contact with air and moisture is avoided, the affinity of magnesium and boron for oxygen is retained in the material, i.e., oxygen initially present in the elements are found in the finished product. Oxygen-free elemental magnesium is difficult or impossible to prepare and store; this applies even more to the element boron.

### SUMMARY

An aspect of the present invention is to provide a quality of magnesium diboride (MgB₂) which can be used as superconducting material in powder-filled wires or as magnesium diboride sintered bodies. The achievable current carrying capacity of the components or wires comprising the magnesium diboride should thereby also be as great as possible at high applied magnetic fields. The achievable sinter activity of the magnesium diboride obtained should also be as great as possible even at low temperature. An alternative aspect of the present invention is to provide a process whereby dopants can be introduced in a simple manner into the magnesium diboride. In the case of doping by means of Si and C compounds, the dopants should be present in very finely dispersed form in the MgB₂, so that a “solid solution” is effectively present. The preparation of MgB₂ should thereby if possible be carried out under reducing conditions in order to avoid contamination by oxidic by-products. The magnesium diboride obtained should also have a very fine particle size and be amorphous to partially crystalline.

In an embodiment, the present invention provides an amorphous or a partially crystalline magnesium diboride comprising a crystalline material content of <25% by weight as determined by an X-ray powder diffraction.

### DETAILED DESCRIPTION

In an embodiment, the present invention provides a two-stage process in which the intermediate magnesium borohydride (Mg(BH₄)₂) is firstly prepared from magnesium hydride (MgH₂) or magnesium alkyls (MgR₂) or magnesium alkoxides (Mg(OR)₂) and borane (B₂H₆), with the oxidic impurities being separated off, and the magnesium borohydride is subsequently thermally decomposed to give magnesium diboride (MgB₂). There are two alternative processes for the first step, the preparation of pure magnesium borohydride, in which either a nonpolar solvent or a polar solvent is used.

In an embodiment (a1), a magnesium alkyl of the general formula MgR₂ or a magnesium alkoxide of the general formula Mg(OR)₂ can be dissolved in a nonpolar solvent. Examples of radicals R are all alkyl radicals having from 1 to 5 carbon atoms, such as: methyl, ethyl, propyl, isopropyl, butyl, isobutyl, sec-butyl, tert-butyl, pentyl, isopentyl and neopentyl. Di(n-butyl)magnesium can, for example, be used. In the case of the alkoxide radicals in Mg(OR)₂, the above definition of the radical R applies analogously: the alkoxides —OR can be derived from the corresponding alcohols. Magnesium di-n-propoxide (Mg(O-n-C₃H₇)₂) can, for example, be used. Examples of nonpolar solvents are: hydrocarbons, such as pentane, hexane, heptane, octane, petroleum ether, benzene, toluene and xylene. Heptane can, for example, be used.

Magnesium alkyls and magnesium alkoxides are sensitive to oxygen and moisture. Magnesium alkyls and magnesium alkoxides therefore always contain magnesium oxide (MgO) or magnesium hydroxide (Mg(OH)₂). When the relatively nonpolar magnesium alkyls or magnesium alkoxides are dissolved in the abovementioned solvents, the magnesium alkyls or magnesium alkoxides go into solution while the oxidic impurities, for example, magnesium oxide (MgO) and magnesium hydroxide (Mg(OH)₂), do not go into solution because of their polar character. The undissolved constituents are separated from the solution of the magnesium alkyls or magnesium alkoxides by a known solid/liquid separation method, for example, by filtration or centrifugation. This gives a solution of the magnesium alkyls or alkoxides which is free of oxidic impurities and into which gaseous diborane (B₂H₆) is passed. The reaction of the magnesium alkyls or magnesium alkoxides can be described by the following reaction equations (1) and (2), which essentially represent a metathesis of the alkyl or alkoxide groups:

3 MgR₂+4 B₂H₆→2 BR₃+3 Mg(BH₄)₂ (1)

3 Mg(OR)₂+4 B₂H₆→2 B(OR)₃+3 Mg(BH₄)₂ (2)

The diborane B₂H₆ used is free of oxygen and moisture since it reacts with oxygen and moisture to form boron oxide and boric acids, respectively. The reaction with diborane forms magnesium borohydride (Mg(BH₄)₂), which precipitates as a polar salt in these solvents. The boron organyles BR₃ or boric esters B(OR)₃ which are at the same time formed in small amounts as by-products, are soluble in the nonpolar solvent because of their nonpolar nature. This also applies to unreacted magnesium alkyls or magnesium alkoxides which likewise remain in solution. Renewed phase separation, for example, by filtration, provides the pure magnesium borohydride (Mg(BH₄)₂) which is free of oxidic impurities in the solid state. This can be used in the second step of thermolysis. During the entire process, oxygen and moisture should be excluded.

In an embodiment (a2), the complex hydride magnesium borohydride (Mg(BH₄)₂) can be prepared from magnesium hydride (MgH₂) and boron hydride (diborane; B₂H₆) in a polar aprotic solvent. This reaction can be described by the following reaction equation:

MgH₂+B₂H₆→Mg(BH₄)₂ (3)

This reaction can, for example, take place in a polar aprotic solvent which has one or more oxygen and/or nitrogen atoms as donor function. These donor atoms have the function of coordinating to the magnesium atom and thus provide that a solution of the magnesium borohydride is formed. Suitable solvents are dipolar aprotic solvents in general, which can comprise the following functional groups: ethers, tertiary amines and amides. Specific examples include diethyl ether, tert-butyl methyl ether, dioxane, tetrahydrofuran, N-methylmorpholine, dimethylformamide and the like. Tert-butyl methyl ether can, for example, be used.

Magnesium hydride is sensitive to oxygen and moisture. Commercial magnesium hydride therefore always contains magnesium oxide (MgO) and/or magnesium hydroxide (Mg(OH)₂). Nevertheless, magnesium hydride is used together with the oxidic impurities in this step of the process of the present invention. Magnesium hydride is insoluble in the solvent mentioned and is slurried therein for the purposes of the reaction. Gaseous diborane is subsequently passed through the slurry of the magnesium hydride, forming magnesium borohydride which dissolves in the donor solvent used.

Magnesium borohydride (Mg(BH₄)₂) dissolves in the solvents mentioned while the oxidic impurities such as MgO and Mg(OH)₂ and also boron oxide and boric acid are insoluble therein. This solubility difference between the soluble magnesium borohydride (Mg(BH₄)₂) and the insoluble oxidic impurities thus allows the oxidic by-products to be separated off from the intermediate magnesium borohydride. In this embodiment (a2), solid/liquid phase separation provides a solution of magnesium borohydride which is free of oxidic impurities. The solvent can be removed by evaporation to provide a solid magnesium borohydride in which the donor solvents are coordinated to the magnesium. In all process steps, oxygen and moisture should be excluded.

A recrystallization step from organic solvents can be carried out to achieve further purification of magnesium borohydride (Mg(BH₄)₂), regardless of whether the magnesium borohydride has been prepared according to embodiment (a1) or (a2). The solvents for the recrystallization are the same as those for embodiment (a2).

In both embodiments (a1 and a2), a pure starting material Mg(BH₄)₂ which is free of oxidic impurities and which is suitable for the preparation of magnesium diboride is obtained. This intermediate Mg(BH₄)₂ can be used in a second step (b) to prepare a magnesium diboride MgB₂ which is also free of oxidic by-products.

Magnesium borohydride (Mg(BH₄)₂) has been found to be an advantageous intermediate since it can be recrystallized from organic solvents.

An advantage of the intermediate magnesium borohydride (Mg(BH₄)₂) is that it is obtained with a soft consistency and a small particle size when prepared. Magnesium borohydride forms a turbid suspension in heptane which settles only slowly. A fine particle size distribution of the magnesium borohydride can be concluded from this. It is difficult to determine a particle size distribution with exclusion of oxygen and moisture. A further after-treatment, such as a milling step to further reduce the particle size, is not necessary.

In a second step (b), the magnesium borohydride (Mg(BH₄)₂) obtained is subjected to thermal decomposition to form magnesium diboride (MgB₂). The thermolysis proceeds according to the following reaction equation:

Mg(BH₄)₂→MgB₂+4 H₂ (4)

The thermolysis of the magnesium borohydride (Mg(BH₄)₂) is carried out at temperatures in the range from 250° C. to 1600° C., for example, at a temperature in the range from 500° C. to 1000° C. The thermolysis can, for example, be carried out at a temperature of from about 500° C. to 600° C. An amorphous to partially crystalline magnesium diboride is thereby obtained. The reactivity toward dopants is significantly higher in the case of the magnesium diboride according to the present invention than that of the crystalline magnesium diboride according to the prior art. The magnesium diboride prepared according to the present invention also has a higher sinter activity than that prepared by the conventional process.

The pressure in the thermolysis reaction can, for example, be atmospheric pressure. A protective gas at atmospheric pressure can, for example, be used. A possible protective gas is, for example, argon. A superatmospheric pressure of hydrogen can also be used. On the other hand, if the thermolysis of the magnesium borohydride is carried out in a high vacuum, reversal of the formation reaction for this compound (see reaction equation (3)) occurs. As a consequence, magnesium hydride and diborane would again be obtained. A reactor for the thermolysis of magnesium borohydride at atmospheric pressure can, for example, be a reactor having a moving bed. Examples include a rotary tube furnace and a fluidized-bed reactor. It is also possible to use a reactor having a static bed.

The thermolysis reaction of the magnesium borohydride has various advantages.

For example, the donor solvents coordinated to the magnesium atom are given off at temperatures as low as from 50 to 250° C. in a stream of argon. The magnesium borohydride is, however, stable to decomposition at these temperatures. The adduct of magnesium borohydride and donor solvent therefore has no disadvantage in terms of having an adverse effect in the decomposition of magnesium borohydride which commences only above 250° C.

Hydrogen is formed as the sole by-product during the thermolysis reaction. Thus, no oxygen which could lead to contamination as a result of the formation of oxidic impurities is formed during the thermolysis or participates in the thermolysis reaction.

The hydrogen formed can easily be separated off from the solid magnesium diboride as a gas. Furthermore, no solvents or auxiliaries which coat the surface of the magnesium diboride being formed are used in this step which may through emission as the case might be impair the superconductivity of the magnesium diboride. Coating of the surface is avoided from the beginning in the process of the present invention, so that no reaction products or by-products can be formed. The formation of hydrogen is therefore also ideal from this perspective.

Magnesium borohydride can be thermolyzed easily and completely. The thermolysis commences at temperatures of about 250° C. The heat of reaction for the formation of magnesium diboride MgB₂ by thermolysis of magnesium borohydride is relatively low compared to the formation from the elements. This situation is an advantage in the preparation of magnesium diboride for use in superconduction. The lower the temperature or the heat of reaction for formation of magnesium diboride, the lower the particle size and crystal growth of the magnesium diboride obtained and the poorer the crystallinity of the magnesium diboride. According to the Tammann rule, crystal growth is particularly great when the temperature of a mixture is close to the theoretical melting point. A high heat of reaction thus promotes crystal growth. However, a very small particle size is preferred for the present use in superconduction.

The pure magnesium diboride MgB₂ formed has an advantage that it is obtained in finely particulate form; it does not have to be subsequently milled because it does not sinter during the thermolysis reaction, it can therefore be used directly as material for filled wires. A milling step would also mean contamination as a result of abrasion. The magnesium diboride MgB₂ obtained has a monomodal particle size distribution of D₁₀₀≦15 μm, for example of D₁₀₀≦10 μm.

The magnesium diboride prepared according to the present invention is, for example, amorphous or partially crystalline. The amorphous or partially crystalline magnesium diboride of the present invention therefore has a proportion of crystalline material of not more than 25% by weight, for example, not more than 15% by weight or, for example, not more than 10% by weight. In contrast, the crystalline magnesium diboride of the prior art (from H. C. Starck) has no significant proportion of amorphous magnesium diboride.

Compared to the virtually exclusively crystalline magnesium diboride of the prior art, the magnesium diboride prepared according to the present invention has an advantage of higher ductility. This materials property is important when powder-filled wires filled with magnesium diboride are processed by drawing and rolling. In addition, the magnesium diboride prepared according to the present invention has a higher current carrying capacity than that of the prior art.

The magnesium diboride prepared by the process of the present invention is free of oxidic impurities and has an oxygen content of not more than 2000 ppm, for example, not more than 500 ppm, or for example, not more than 100 ppm.

In addition, the magnesium diboride prepared by the process of the present invention can readily be doped. In the prior art, doping is usually carried out by milling magnesium diboride or its starting materials with the dopant. Abrasion during milling therefore represents a source of contamination. Doping of the magnesium diboride intended for superconducting applications with various materials promotes high current carrying capacities or current densities. Doping with carbon or silicon carbide or doping with a mixture of the two is particularly sought after by wire manufacturers.

According to the present invention, doping is carried out using gases which are added to the protective gas in the step of thermolysis of the magnesium borohydride. This provides a particularly fine dispersion of the dopant, namely the desired “solid solution”, to be achieved. Doping with carbon (C doping) can be achieved in the thermolysis process by enriching the protective gas with gases which give carbon on decomposition. Suitable gases are, for example, acetylene, ethylene, propane and butane. Acetylene can, for example, be used.

Various methylsilanes which on thermolysis provide silicon carbide, possibly with an excess of one element, are possible for doping with silicon carbide. Examples of methylsilanes are tetramethylsilane (Si(CH₃)₄) and tetramethyldisilylene ((CH₃)₂Si=Si(CH₃)₂). Tetramethylsilane (Si(CH₃)₄) can, for example, be used. It is also possible to use further compounds, such as gases, which can be decomposed to form the desired dopants during the thermolysis process.

The magnesium diboride of the present invention can, due to its high purity and its fine, homogeneous particle size distribution, be employed in superconduction. Here, a metal wire containing a core of magnesium diboride is used.

The conventional methods of wire manufacture place various demands on the magnesium diboride which have hitherto not been able to be met. Such a wire can be obtained in a conventional way by enclosing a mixture of elemental boron and magnesium in a metal sheath, subsequently drawing a wire and then carrying out a heat treatment to bring about a chemical reaction of boron and magnesium to form magnesium diboride and obtain a metal wire having a magnesium diboride core.

Apart from a high proportion of amorphous boron, a high purity, in particular a low content of oxygen, nitrogen, anionic impurities such as chloride or fluoride and also usual metallic impurities such as alkali metal and alkaline earth metal ions and also other metal ions, is required. Likewise, a low particle size and the absence of oversize individual particles is demanded, since these individual particles lead to rupture of the wire during drawing and impurities can result in a lower current carrying capacity.

Furthermore, oversize individual particles (“oversize”) prevent complete chemical reaction of the boron with magnesium to form magnesium diboride.

Conventional, commercially available boron is usually obtained by reduction of boron trioxide with magnesium. There is therefore a need for further purification of the commercial boron in order to make further inexpensive production possible.

As an alternative, such a superconducting wire can be obtained by enclosing the magnesium diboride in a metal sheath and subsequently drawing a wire. The magnesium diboride of the present invention or the magnesium diboride obtained by the process of the present invention is particularly suitable for this manufacturing method since, owing to its high purity, uniform particle size distribution and the small particle size, it overcomes many disadvantages of the prior art.

The present invention therefore also provides a process for producing superconducting wires having a metal sheath and a core of magnesium diboride, wherein magnesium diboride according to the present invention is provided, enclosed in a metal sheath and subsequently converted into a wire having a metal sheath and a core of magnesium diboride by wire drawing.

The present invention is not limited to embodiments described herein; reference should be had to the appended claims.

1-9. (canceled)

10. An amorphous or a partially crystalline magnesium diboride comprising a crystalline material content of ≦25% by weight as determined by an X-ray powder diffraction.

11. The magnesium diboride as recited in claim 10, wherein the magnesium diboride has an oxygen content of ≦2000 ppm.

12. The magnesium diboride as recited in claim 10, wherein the magnesium diboride has a monomodal particle size distribution with a D₁₀₀ of ≦15 μm.

13. A process for preparing an amorphous or a partially crystalline magnesium diboride comprising a crystalline material content of ≦25% by weight as determined by an X-ray powder diffraction, the process comprising:
reacting at least one of a magnesium alkyl (MgR₂) and a magnesium alkoxide (Mg(OR)₂), where R is an alkyl radical having from 1 to 5 carbon atoms, with diborane (B₂H₆) in a nonpolar solvent so as to form magnesium borohydride (Mg(BH₄)₂); and
separating off oxidic impurities and by-products; or
reacting magnesium hydride (MgH₂) with diborane (B₂H₆) in a dipolar aprotic solvent so as to form magnesium borohydride (Mg(BH₄)₂); and
separating off oxidic impurities; and
thermolyzing the magnesium borohydride (Mg(BH₄)₂) at atmospheric pressure and at a temperature of from 250° C. to 1600° C. under a protective gas atmosphere so as to form the magnesium diboride.

14. The process as recited in claim 13, further comprising recrystallizing the magnesium borohydride (Mg(BH₄)₂) in a dipolar aprotic solvent.

15. The process as recited in claim 13, wherein the protective gas atmosphere includes at least one of a carbon and silicon doping gas and the magnesium borohydride (Mg(BH₄)₂) is thermolyzed so as to be doped with at least one of carbon and silicon as a solid solution.

16. Process of using an amorphous or a partially crystalline magnesium diboride comprising a crystalline material content of ≦25% by weight as determined by an X-ray powder diffraction for superconductivity, the process comprising:
providing an amorphous or a partially crystalline magnesium diboride comprising a crystalline material content of ≦25% by weight as determined by an X-ray powder diffraction; and
using the magnesium diboride for superconductivity.

17. A process for producing a superconducting wire, the process comprising:
providing an amorphous or a partially crystalline magnesium diboride comprising a crystalline material content of ≦25% by weight as determined by an X-ray powder diffraction;
providing a metal sheath;
enclosing the magnesium diboride in the metal sheath; and
drawing the metal sheath so as to obtain a metal wire comprising the metal sheath and a core comprising the magnesium diboride.

18. The process as recited in claim 17, wherein the magnesium diboride is provided by:
reacting at least one of a magnesium alkyl (MgR₂) and a magnesium alkoxide (Mg(OR)₂), where R is an alkyl radical having from 1 to 5 carbon atoms, with diborane (B₂H₆) in a nonpolar solvent so as to form magnesium borohydride (Mg(BH₄)₂); and
separating off oxidic impurities and by-products; or
reacting magnesium hydride (MgH₂) with diborane (B₂H₆) in a dipolar aprotic solvent so as to form magnesium borohydride (Mg(BH₄)₂); and
separating off oxidic impurities; and
thermolyzing the magnesium borohydride (Mg(BH₄)₂) at atmospheric pressure and at a temperature of from 250° C. to 1600° C. under a protective gas atmosphere so as to form the magnesium diboride.
